(19) United States
(12) Patent Application Publication
(10) Pub. No.: US 2024/0021770 A1
(43) Pub. Date: Jan. 18, 2024

(54) DISPLAY DEVICE AND MANUFACTURING METHOD THEREOF

(71) Applicant: Samsung Display Co., LTD., Yongin-si (KR)

(72) Inventors: Hwang Sup SHIN, Yongin-si (KR); Suk Hoon KU, Yongin-si (KR); Eung Taek KIM, Yongin-si (KR); Hee Yeon KIM, Yongin-si (KR); Na Lae LEE, Yongin-si (KR); Joo Hyeon JO, Yongin-si (KR); Jung-Mi CHOI, Yongin-si (KR); HONGJUN CHOI, Yongin-si (KR)

(73) Assignee: Samsung Display Co., LTD., Yongin-si (KR)

(21) Appl. No.: 18/336,200

(22) Filed: Jun. 16, 2023

(30) Foreign Application Priority Data
Jul. 14, 2022 (KR) 10-2022-0086978

(51) Int. Cl. H01L 33/62; H01L 25/16; H01L 33/02; H01L 33/00

(52) U.S. Cl. CPC H01L 33/62; H01L 25/167; H01L 33/025; H01L 33/0095

(57) ABSTRACT

An embodiment of the invention provides a display device including: a substrate; a first transistor comprising a first semiconductor layer and a second transistor comprising a second semiconductor layer, the first and second semiconductor layers positioned on the substrate; a light emitting diode connected to the first transistor, wherein: the first transistor is a driving transistor; the second transistor is a switching transistor; a first concentration of fluorine included in the first semiconductor layer is higher than a second concentration of fluorine in the second semiconductor layer; and a first difference between the first and second concentrations substantially at or near a first interface of the first and second semiconductor layers is larger than a second difference between the first and second concentrations at a second interface of the first and second semiconductor layers, the second interface further from the substrate than the first interface.

### CROSS-REFERENCE TO RELATED APPLICATION

This application claims priority to and the benefits of Korean Patent Application No. 10-2022-0086978 under 35 U.S.C. § 119, filed in the Korean Intellectual Property Office (KIPO) on Jul. 14, 2022, the entire contents of which are incorporated herein by reference.

### BACKGROUND

### 1. Technical Field

The disclosure relates to a display device and a manufacturing method thereof, and more particularly, to a transistor in which fluorine concentrations of a driving transistor and a switching transistor are different.

### 2. Description of the Related Art

Recently, an organic light emitting diode display has attracted attention as a device for displaying an image.

Since the organic light emitting diode display has a self-emission characteristic and does not require an additional light source, unlike a liquid crystal display device, it is possible to reduce thickness and weight thereof. Further, the organic light emitting diode display has high-quality characteristics such as low power consumption, high luminance, and high response speed.

Generally, the organic light emitting diode display includes a substrate, a plurality of thin film transistors positioned on the substrate, a plurality of insulating layers disposed between wires included in the thin film transistors, and an organic light emitting diode connected to the thin film transistors.

The organic light emitting diode display includes a plurality of pixels, and each pixel includes a plurality of transistors.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a display device configured to have reliability at a high temperature while effectively improving an afterimage, and a manufacturing method thereof.

An embodiment of the invention provides a display device including a first transistor comprising a first semiconductor layer and a second transistor comprising a second semiconductor layer, the first and second semiconductor layers positioned on a substrate; and a light emitting diode connected to the first transistor; wherein the first transistor is a driving transistor, the second transistor is a switching transistor, a first concentration of fluorine in the first semiconductor layer is higher than a second concentration of fluorine in the second semiconductor layer, and a first difference between the first and second concentrations substantially at or near a first interface of the first and second semiconductor layers is larger than a second difference between the first and second concentrations at a second interface of the first and second semiconductor layers, the second interface further from the substrate than the first interface.

The first difference between the first and second concentrations may be 2 to 10 times the second concentration.

The display device may further include a barrier layer that is positioned between the substrate and the first transistor and between the substrate and the second transistor, wherein a third concentration of fluorine in an area of the barrier layer overlapping the first semiconductor layer may be higher than a fourth concentration of fluorine in an area of the barrier layer overlapping the second semiconductor layer.

The third concentration may be 2 to 10 times the fourth concentration.

The first difference between the first and second concentrations may be larger than a third difference between the third concentration and the fourth concentration.

The first semiconductor layer and the second semiconductor layer may be positioned on the same layer.

The fluorine concentration may be measured by comparing Secondary-ion mass spectrometry (SIMS) Intensity. The display device may further include a driving voltage line, a common voltage line, a data line, a scan line, a previous scan line, a bypass control line, an initialization voltage line, a third transistor, a fourth transistor, a fifth transistor, a sixth transistor, and a seventh transistor that are positioned on the substrate, wherein the first transistor may include a first electrode electrically connected to a second electrode of the fifth transistor and a second electrode electrically connected to a first electrode of the third transistor, and may be constructed and arranged to control a driving current by application of a data voltage; the second transistor may include a first electrode electrically connected to the data line and a second electrode electrically connected to a first electrode of the first transistor, and may be constructed and arranged to turn on according to a scan signal of the scan line; the third transistor may include a first electrode electrically connected to a second electrode of the first transistor and a second electrode electrically connected to a gate electrode of the first transistor, and may be constructed and arranged to turn on according to the scan signal of the scan line; the fourth transistor may include a first electrode electrically connected to the initialization voltage line and a second electrode electrically connected to a second electrode of the third transistor, and may be constructed and arranged to turn on according to a previous scan signal received through the previous scan line; the fifth transistor may include a first electrode electrically connected to the driving voltage line and a second electrode electrically connected to the first electrode of the first transistor, and may be constructed and arranged to turn on by an emission signal of the emission control line; the sixth transistor may include a first electrode electrically connected to the second electrode of the first transistor and a second electrode electrically connected to an anode of the light emitting diode, and may be constructed and arranged to turn on by the emission signal of the emission control line; the seventh transistor may include a first electrode electrically connected to the anode of the light emitting diode and a second electrode electrically connected to the initialization voltage line, and may be constructed and arranged to turn on according to a bypass signal of the bypass control line; and the first concentration of fluorine included in the first semiconductor layer of the first transistor may be higher than concentrations of fluorine included in a third semiconductor layer of the third transistor, a fourth semiconductor layer of the fourth transistor, a fifth semiconductor layer of the fifth transistor, a sixth semiconductor layer of the sixth transistor, and a seventh semiconductor layer of the seventh transistor.

Another embodiment provides a manufacturing method of a display device, including forming a semiconductor layer on a substrate; positioning a photoresist on the semiconductor layer; forming an opening in the photoresist that exposes a portion of the semiconductor layer; doping an area of the exposed semiconductor layer with fluorine; and etching the semiconductor layer to form a first semiconductor layer and a second semiconductor layer, wherein the first semiconductor layer may be formed in the fluorine-doped area.

A fluorine concentration of the first semiconductor layer may be higher than a fluorine concentration of the second semiconductor layer.

A fluorine concentration of the first semiconductor layer may be 2 to 10 times a fluorine concentration of the second semiconductor layer.

The manufacturing method of the display device may further include forming a barrier layer between the substrate and the semiconductor layer, wherein a fluorine concentration in an area of the barrier layer overlapping the first semiconductor layer may be higher than a fluorine concentration in an area of the barrier layer overlapping the second semiconductor layer.

A fluorine concentration in an area of the barrier layer overlapping the first semiconductor layer may be 2 to 10 times a fluorine concentration in an area of the barrier layer overlapping the second semiconductor layer.

The manufacturing method of the display device may further include crystallizing the first semiconductor layer and the second semiconductor layer.

Another embodiment provides a manufacturing method of a display device, including forming a semiconductor layer on a substrate; patterning the semiconductor layer to form a first semiconductor layer and a second semiconductor layer; positioning a photoresist on the first semiconductor layer and the second semiconductor layer; forming an opening in the photoresist that exposes the first semiconductor layer; and doping the first semiconductor layer with fluorine.

A fluorine concentration of the first semiconductor layer may be higher than a fluorine concentration of the second semiconductor layer.

A fluorine concentration of the first semiconductor layer may be 2 to 10 times a fluorine concentration of the second semiconductor layer.

The manufacturing method of the display device may further include forming a barrier layer between the substrate and the semiconductor layer, wherein a fluorine concentration in an area of the barrier layer overlapping the first semiconductor layer may be higher than a fluorine concentration in an area of the barrier layer overlapping the second semiconductor layer.

A fluorine concentration in an area of the barrier layer overlapping the first semiconductor layer may be 2 to 10 times a fluorine concentration in an area of the barrier layer overlapping the second semiconductor layer.

The manufacturing method of the display device may further include crystallizing the first semiconductor layer and the second semiconductor layer.

According to the embodiments, a display device that may have reliability at a high temperature while effectively improving an afterimage and a manufacturing method thereof are provided.

### BRIEF DESCRIPTION OF THE DRAWINGS

The above and other aspects and features of the disclosure will become more apparent by describing in detail embodiments thereof with reference to the attached drawings, in which:

FIG. 1 illustrates a schematic diagram of an equivalent circuit of a display device according to an embodiment.

FIG. 2 is a schematic cross-sectional view of a display device according to an embodiment.

FIG. 3 schematically illustrates generation of an afterimage of a display device.

FIG. 4 schematically illustrates a change in a device in a case that fluorine is injected.

FIG. 5 schematically illustrates that a positive shift of a threshold voltage of a semiconductor device occurs in a high temperature reliability test.

FIG. 6 schematically illustrates a threshold voltage shift of a driving transistor by fluorine injection.

FIG. 7 schematically illustrates a threshold voltage shift of a switching transistor of a display device according to an embodiment.

FIG. 8 schematically illustrates structures of a first transistor, which is a driving transistor, and a second transistor, which is a switching transistor.

FIG. 9 schematically illustrates results of measuring fluorine concentration (A-A′) for each area of the first transistor of FIG. 8 and fluorine concentration (B-B′) for each area of the second transistor of FIG. 8.

FIG. 10 schematically illustrates an embodiment in which a semiconductor layer is etched to form a first semiconductor layer and a second semiconductor layer, and then fluorine doping is performed.

FIG. 11 schematically illustrates an embodiment in which a semiconductor layer is etched after doping with fluorine.

FIG. 12 to FIG. 16 illustrate a configuration of doping fluorine by the same method as in FIG. 10.

FIG. 17 to FIG. 21 illustrate a configuration of doping fluorine by the same method as in FIG. 11.

FIG. 22 to FIG. 25 illustrate a configuration of doping fluorine by the same method as in FIG. 11 with respect to a semiconductor layer having a different structure.

FIG. 26 to FIG. 29 illustrate a configuration of doping fluorine by the same method as in FIG. 10 with respect to a semiconductor layer having a different structure.

FIG. 30 illustrates a schematic diagram of an equivalent circuit of one pixel in a light emitting display device according to an embodiment, and FIG. 31 illustrates a timing chart of a signal applied to one pixel of a light emitting display device according to an embodiment.

FIG. 32 schematically illustrates a layout view of one pixel area of a light emitting display device according to an embodiment, and FIG. 33 is a schematic cross-sectional view taken along line X-X′ in FIG. 32.

### DETAILED DESCRIPTION OF THE EMBODIMENTS

The disclosure will be described more fully hereinafter with reference to the accompanying drawings, in which embodiments of the invention are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In order to clearly describe the embodiment, parts or portions that are irrelevant to the description are omitted, and identical or similar constituent elements throughout the specification are denoted by the same reference numerals.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

It will be understood that when an element such as a layer, film, region, area, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

Further, throughout the specification, the phrase “in a plan view” means viewing the object from the top, and the phrase “in a schematic cross-sectional view” means viewing a cross-section of which the object is vertically cut from the side.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween. It will be understood that the terms “connected to” or “coupled to” may include a physical or electrical connection or coupling.

Hereinafter, a display device according to an embodiment of the invention will be described in detail with reference to the accompanying drawings.

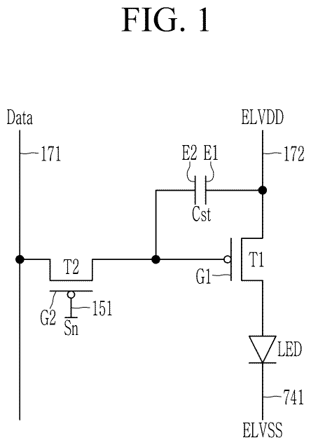

FIG. 1 illustrates a schematic diagram of an equivalent circuit of a display device according to an embodiment. Referring to FIG. 1, a display device according to the embodiment includes a first transistor T1, a second transistor T2, and a storage capacitor Cst. The first transistor T1 is a driving transistor, and one end thereof is electrically connected to a driving voltage line 172 and the other end thereof is electrically connected to a light emitting diode LED.

The second transistor T2 is a switching transistor, and one end thereof is electrically connected to a data line 171 to receive a data voltage (Data) and the other end thereof is electrically connected to a gate electrode G1 of the first transistor T1. A first electrode E1 of the storage capacitor Cst may be connected to the driving voltage line 172, and a second electrode E2 thereof may be connected to the gate electrode G1 of the first transistor T1. In this display device, a driving voltage of the first transistor T1 is transmitted to the light emitting diode LED according to a switching operation of the second transistor T2. The light emitting diode LED is electrically connected to a common voltage line 741 to receive a common voltage ELVSS, and is electrically connected to the first transistor T1 to receive a driving voltage ELVDD to emit light.

In the display device according to the embodiment, a fluorine concentration of the first transistor T1 is higher than that of the second transistor T2. That is, only a semiconductor layer of the first transistor T1 is selectively doped with fluorine, thereby improving an afterimage of the display device. Hereinafter, a specific structure and effect will be described.

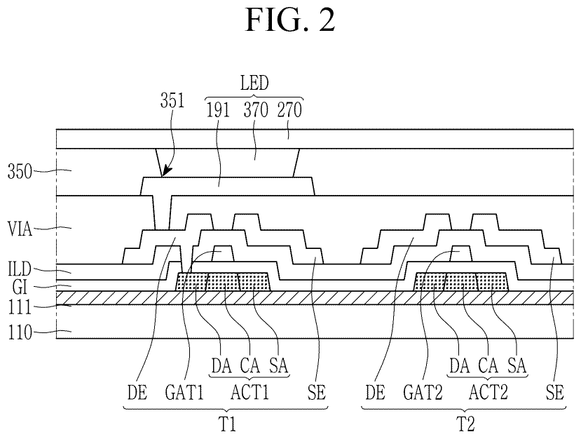

FIG. 2 is a schematic cross-sectional view of a display device according to an embodiment. Referring to FIG. 2, a substrate 110, a barrier layer 111 positioned on the substrate 110, and a first semiconductor layer ACT1 and a second semiconductor layer ACT2 positioned on the barrier layer 111 are included. As illustrated in FIG. 2, the first semiconductor layer ACT1 and the second semiconductor layer ACT2 may be formed or positioned in the same semiconductor layer.

Each semiconductor layer (e.g., ACT1, ACT2) includes a source area SA, a channel area CA, and a drain area DA. A gate insulating film GI is positioned on the first semiconductor layer ACT1 and the second semiconductor layer ACT2. A first gate electrode GAT1 and a second gate electrode GAT2 are positioned on the gate insulating film GI. Each of the gate electrodes GAT1 and GAT2 is positioned to overlap the channel area CA of each of the semiconductor layers ACT1 and ACT2.

An interlayer insulating film ILD may be positioned on the gate electrodes GAT1 and GAT2. A data conductive layer including a drain electrode DE and a source electrode SE may be positioned on the interlayer insulating film ILD. The drain electrode DE of the first transistor T1 is electrically connected to the drain area DA of the first semiconductor layer ACT1 through a contact hole positioned in the interlayer insulating film ILD and the gate insulating film GI.

An insulating film VIA is positioned on the data conductive layer. A first electrode 191 may be positioned on the insulating film VIA. The first electrode 191 is electrically connected to the drain electrode DE of the first transistor T1 through the contact hole of the insulating film. A partition wall 350 is positioned on the insulating film VIA, and the partition wall 350 has an opening 351 overlapping the first electrode 191. A light emitting element layer 370 may be positioned in the opening 351 of the partition wall 350, and a second electrode 270 may be positioned on the light emitting element layer 370. The first electrode 191, the light emitting element layer 370, and the second electrode 270 configure the light emitting diode LED.

In FIG. 2, the fluorine content of the first semiconductor layer ACT1 and the second semiconductor layer ACT2 are different. Specifically, the fluorine concentration in a lower area of the first semiconductor layer ACT1 in contact with the barrier layer 111 may be 2 to 10 times the fluorine concentration in a lower area of the second semiconductor layer ACT2 in contact with the barrier layer 111. Even in a case of the barrier layer 111, the fluorine concentration of the barrier layer 111 overlapping the first semiconductor layer ACT1 is higher than that of the barrier layer 111 overlapping the second semiconductor layer ACT2. Specifically, the fluorine concentration in an area of the barrier layer 111 overlapping the first semiconductor layer ACT1 may be 2 to 10 times the fluorine concentration in an area of the barrier layer 111 overlapping the second semiconductor layer ACT2. In this case, the fluorine concentration may be measured by using Secondary-ion mass spectrometry (SIMS) Intensity.

As described above, in a case that the fluorine concentration of the first semiconductor layer ACT1 is higher than that of the second semiconductor layer ACT2, an afterimage may be effectively improved while securing reliability. Hereinafter, effects will be described.

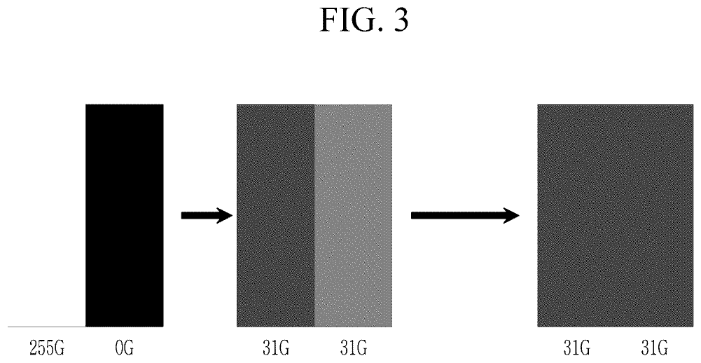

After a user maintains a white or black screen in the display device for a long period of time, an afterimage occurs upon switching to gray. FIG. 3 illustrates a configuration in which an afterimage is generated in this way. As shown in FIG. 3, in a case that a screen on which 255G and 0G are displayed for a long time is changed to 31G, a screen on which a gray of 255G is displayed decreases in luminance to be displayed darker than 31G, and a screen on which a gray of 0G is displayed increases in luminance to be displayed brighter than 31G. As shown in FIG. 3, such an afterimage is restored over time, but in a case that a user maintains a white or black pattern for a long time, a problem in which the existing screen remains when a screen is switched may occur.

For this purpose, in a case that the semiconductor layer is doped with fluorine, an afterimage is improved. Fluorine injected into the semiconductor layer (for example, P-Si) and the barrier layer (for example, SiOx) traps negative charges when the light emitting diode operates. Negative charges are accumulated in a lower portion of the channel of the transistor through the negative charge trap, which increases DR of the driving transistor and prevents a decrease in luminance and improves an afterimage.

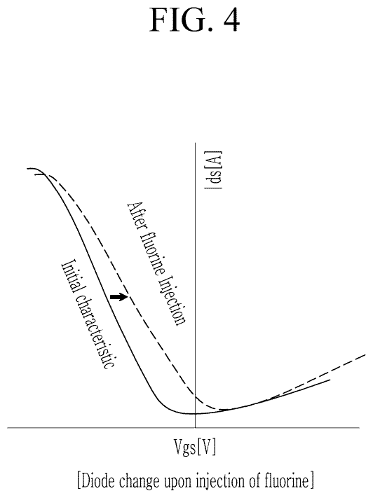

FIG. 4 illustrates a change in a device in a case that fluorine is injected. As can be seen in FIG. 4, it was confirmed that after fluorine injection, a V-I graph as a whole shifted to the right, and a threshold voltage positively shifted.

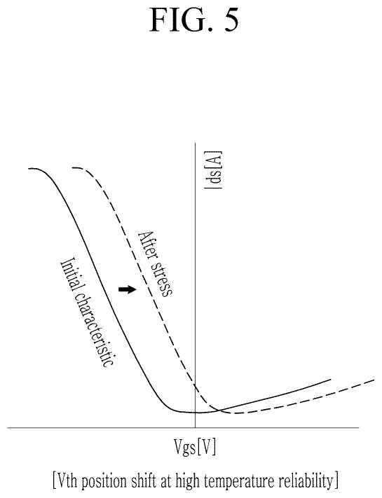

However, in the case of semiconductor devices, the threshold voltage is positively shifted even in a high-temperature environment. FIG. 5 illustrates that a positive shift of a threshold voltage of a semiconductor device occurs in a high temperature reliability test.

Accordingly, in a case that a threshold voltage Vth of the transistor is positively shifted by fluorine doping, a switching operation may not occur under a high temperature stress environment. This is because the threshold voltage is increased by fluorine doping and is additionally increased at a high temperature, so that a Vth margin for the switching operation is insufficient. Therefore, in a case that fluorine is injected into the semiconductor layer, it is effective to improve afterimages, but reliability problems may occur at high temperatures.

However, in the display device according to the embodiment, only the driving transistor (e.g., T1 of FIGS. 1 and 2) is doped with fluorine, and the switching transistor (e.g., T2 of FIGS. 1 and 2) is not doped with fluorine. Therefore, the afterimage may be effectively improved without affecting the switching operation.

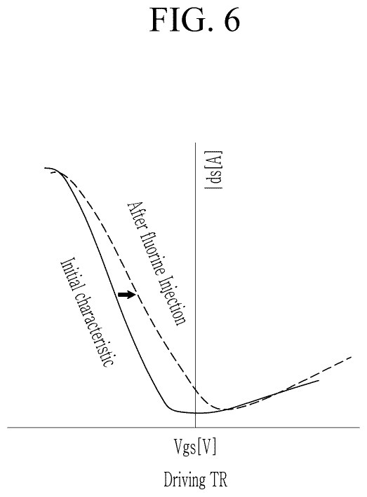

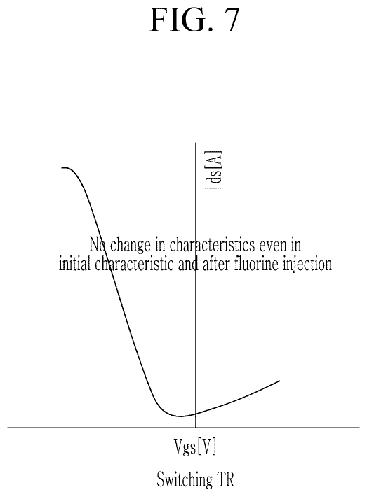

FIG. 6 illustrates a threshold voltage shift of a driving transistor (e.g., T1 of FIGS. 1 and 2) by fluorine injection. Referring to FIG. 6, the threshold voltage Vth of the driving transistor is positively shifted by fluorine injection. Therefore, the afterimage may be effectively improved. FIG. 7 illustrates a threshold voltage shift of a switching transistor (e.g., T2 of FIGS. 1 and 2) of a display device according to the embodiment. Referring to FIG. 7, since the switching transistor is not doped with fluorine, there is no change in the threshold voltage. Therefore, the afterimage may be effectively improved without degrading the high-temperature reliability.

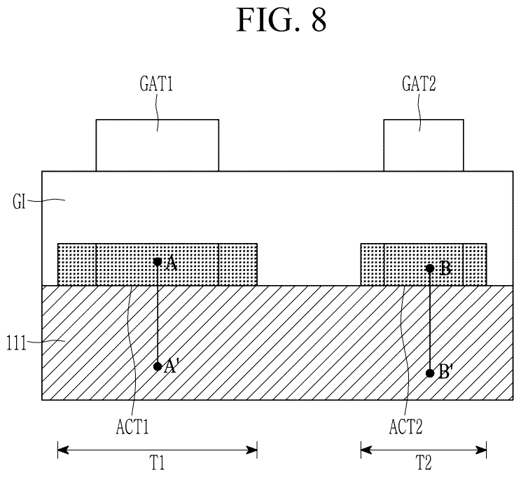

FIG. 8 illustrates a schematic diagram of the structure of the first transistor T1 constructed and arranged to operate as a driving transistor and the second transistor T2 constructed and arranged to operate as a switching transistor. FIG. 8 provides a simplified illustration of the barrier layer 111, the first semiconductor layer ACT1, the second semiconductor layer ACT2, the gate insulating film GI, the first gate electrode GAT1, and the second gate electrode GAT2.

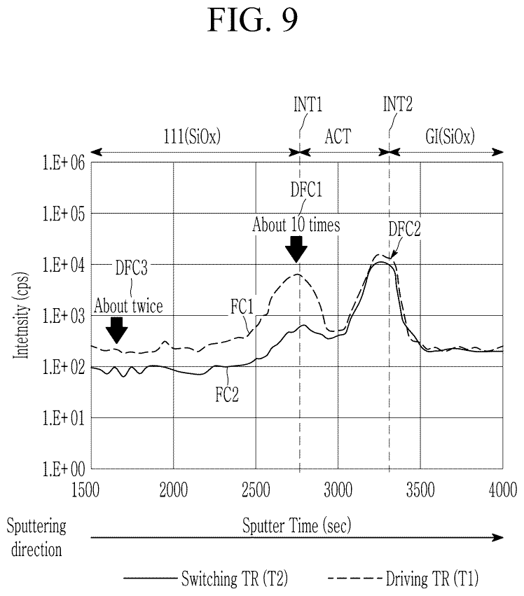

The fluorine concentration of the first transistor T1 was measured along line A-A′ of FIG. 8 and the fluorine concentration of the second transistor T2 was measured along line B-B′ thereof, which are shown in FIG. 9. That is, FIGS. 8 and 9 illustrate the results of measuring the fluorine concentration (A-A′) (FC1 of FIG. 9) for each area of the first transistor and the fluorine concentration (B-B′) (FC2 of FIG. 9) for each area of the second transistor. The fluorine concentration of FIG. 9 was measured by using SIMS Intensity.

Referring to FIG. 9, it was confirmed by measurement that a first concentration of fluorine FC1 in the first semiconductor layer ACT1, measured as intensity in counts per second (cps), was entirely and substantially higher than a second concentration FC2 of fluorine in the second semiconductor layer ACT2. Specifically, it was confirmed that a first difference DFC1 between the fluorine concentrations of the first semiconductor layer ACT1 (FC1) and the second semiconductor layer ACT2 (FC2), substantially at or near a first interface INT1 between the barrier layer 111 and the semiconductor layer ACT, was about 10 times the second concentration FC2 in the second semiconductor layer ACT 2 (e.g., DFC1=FC1−FC2≈10*FC2). The term “substantially at or near” the first interface INT1 as used herein with respect to the first concentration FC1 and the second concentration FC2 refers to a distance from the first interface INT1 of about fifteen percent (15%) the thickness of the semiconductor layer ACT or less.

Referring to FIG. 9, it was further confirmed that a second difference DFC2 between the fluorine concentrations of the first semiconductor layer ACT1 (FC1) and the second semiconductor layer ACT2 (FC2), at a second interface INT2 between the gate insulating film GI and the semiconductor layer ACT (forming the semiconductor layers ACT1 and ACT2), was less than the first difference DFC1 (e.g., DFC2<DFC1). Hence, the first difference DFC1 is larger than the second difference DFC2, where the second interface INT2 is further from the substrate (110 of FIG. 1) than the first interface INT1.

In addition, even in the barrier layer 111, it was confirmed that a difference DFC3 between the fluorine concentrations of the barrier layer under the first semiconductor layer ACT1 and the barrier layer 111 under the second semiconductor layer ACT2 was about two times the fluorine concentration FC2 of the second semiconductor layer ACT 2 (e.g., DFC3=FC1−FC2≈2*FC2). This is because, after doping the semiconductor layer with fluorine, diffusion of fluorine occurs during the crystallization of the semiconductor layer and the doped fluorine diffuses into the barrier layer 111.

In FIG. 9, the fluorine concentrations on an upper surface of the first semiconductor layer ACT1 (FC1) and on an upper surface of the second semiconductor layer ACT2 (FC2) were similar (e.g., FC1≈FC2). This is due to the effect of fluorine used in the semiconductor layer etching process. As shown in FIG. 9, a difference in fluorine concentration between the first semiconductor layer and the second semiconductor layer on the lower surface of the semiconductor layer is larger than a difference in fluorine concentration between the first semiconductor layer and the second semiconductor layer on the center and upper surface of the semiconductor layer. This is due to the diffusion of doped fluorine and the influence of fluorine used in the etching process, as described above.

As in the embodiment, in order to dope only the first semiconductor layer ACT1 of the first transistor T1 with fluorine and to not dope the semiconductor layer ACT2 of the second transistor T2 with fluorine, the semiconductor layer may be etched and then selectively doped, or the semiconductor layer may be selectively doped and then etched.

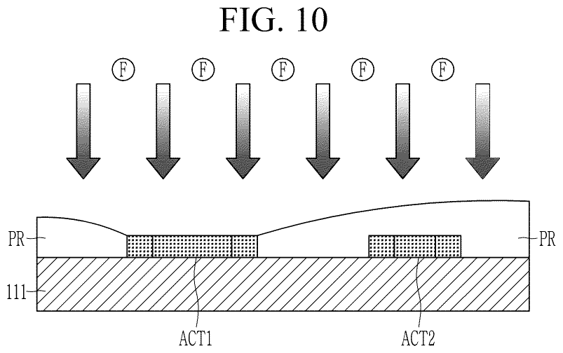

FIG. 10 illustrates an embodiment in which a semiconductor layer is etched to form the first semiconductor layer ACT1 and the second semiconductor layer ACT2 on the same semiconductor layer, and then fluorine doping is performed. As shown in FIG. 10, after the first semiconductor layer ACT1 and the second semiconductor layer ACT2 are formed, a photoresist (e.g., a photoresist layer) PR is positioned and only the first semiconductor layer ACT1 is exposed, and then the first semiconductor layer ACT1 may be selectively doped.

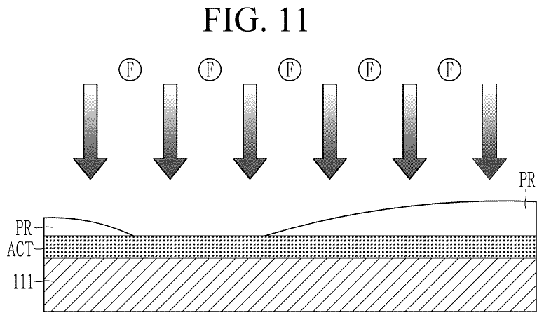

FIG. 11 illustrates an embodiment in which a semiconductor layer ACT is etched after doping with fluorine. Referring to FIG. 11, after a semiconductor layer ACT is entirely deposited, the photoresist PR is positioned. The photoresist PR includes an opening exposing an area to be formed as the first semiconductor layer ACT1, and the exposed semiconductor layer is doped with fluorine. Thereafter, the semiconductor layer may be etched to form the first semiconductor layer ACT1 and the second semiconductor layer ACT2.

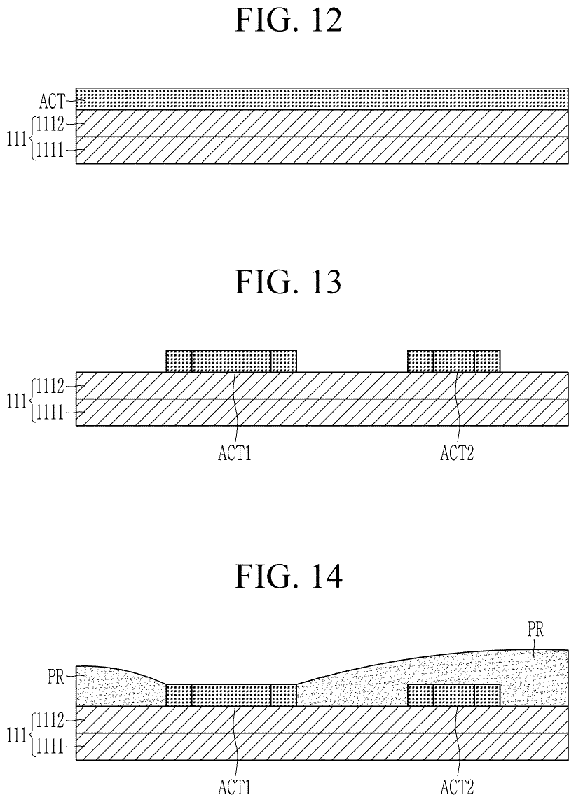

FIG. 12 to FIG. 16 illustrate in detail a configuration of doping fluorine by the same method as in FIG. 10. Referring to FIG. 12, the semiconductor layer ACT is formed on the barrier layer 111. The barrier layer 111 may have a multi-layered structure including a first layer 1111 including a SiNx and a second layer 1112 including a SiOx, but is not limited thereto.

Next, referring to FIG. 13, the semiconductor layer ACT is etched to form the first semiconductor layer ACT1 and the second semiconductor layer ACT2 formed on the same semiconductor layer (ACT of FIG. 12).

Next, referring to FIG. 14, the photoresist PR is formed on the first semiconductor layer ACT1 and the second semiconductor layer ACT2. In this case, the photoresist PR has an opening overlapping the first semiconductor layer ACT1. Therefore, the first semiconductor layer ACT1 is exposed without overlapping the photoresist PR.

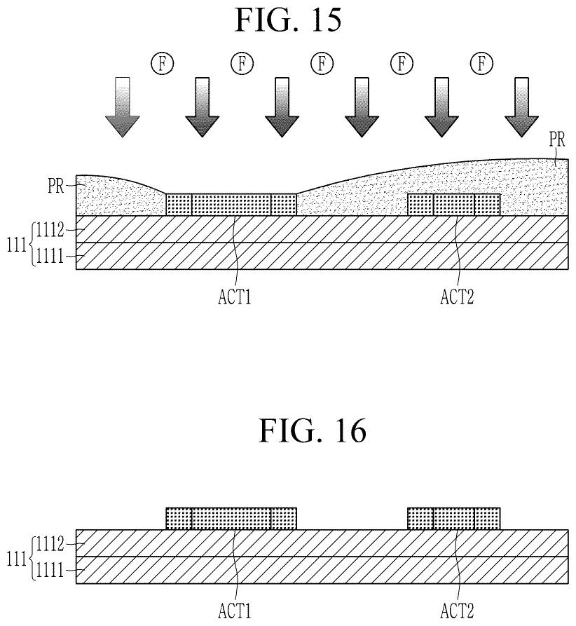

Next, referring to FIG. 15, fluorine is doped. In this case, the fluorine is doped only in the first semiconductor layer ACT1 that is not covered by the photoresist PR. Since an upper surface of the second semiconductor layer ACT2 is covered with the photoresist PR, it is not doped with fluorine.

Next, referring to FIG. 16, the photoresist PR is removed. Accordingly, a structure in which the first semiconductor layer ACT1 is doped with fluorine and the second semiconductor layer ACT2 is not doped with fluorine is formed.

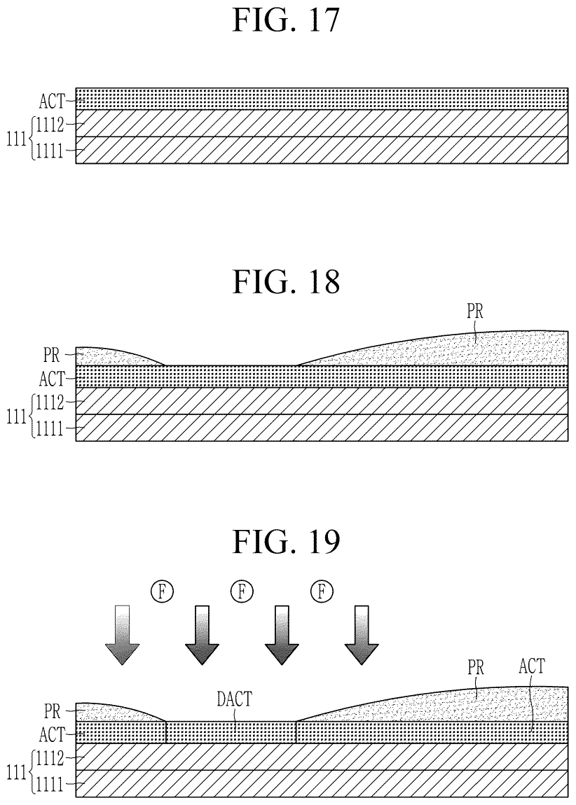

FIG. 17 to FIG. 21 illustrate in detail a configuration of doping fluorine by the same method as in FIG. 11. Referring to FIG. 17, the semiconductor layer ACT is formed on the barrier layer 111. The barrier layer may have a multi-layered structure including the first layer 1111 including a SiNx and the second layer 1112 including a SiOx, but is not limited thereto.

Next, referring to FIG. 18, the photoresist PR is formed on the semiconductor layer ACT. In this case, the photoresist PR has an opening overlapping a partial area of the semiconductor layer ACT. Accordingly, the partial area of the semiconductor layer is exposed without overlapping with the photoresist PR.

Next, referring to FIG. 19, fluorine is doped. In this case, fluorine is doped only in the semiconductor layer that is not covered by the photoresist PR. FIG. 19 illustrates a semiconductor layer area DACT doped with fluorine. This is a portion that is then etched as the first semiconductor layer.

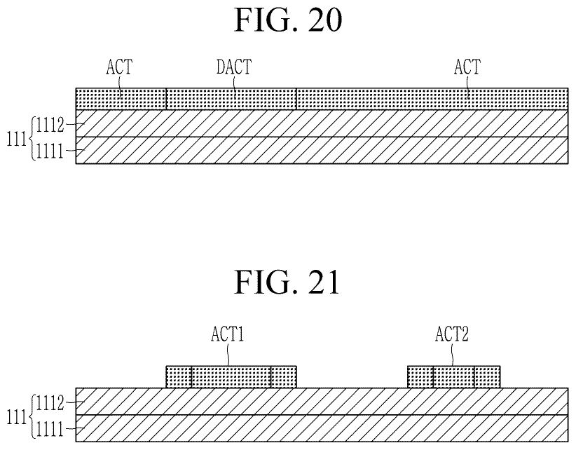

Next, referring to FIG. 20, the photoresist PR is removed.

Next, referring to FIG. 21, the first semiconductor layer and the second semiconductor layer are formed by etching the semiconductor layer. In this case, the semiconductor layer area DACT doped with fluorine becomes the first semiconductor layer ACT1. Accordingly, a structure in which the first semiconductor layer is doped with fluorine and the second semiconductor layer is not doped with fluorine is formed.

A structure including two transistors and one capacitor has been described above, but this is only an example, and the disclosure is not limited thereto.

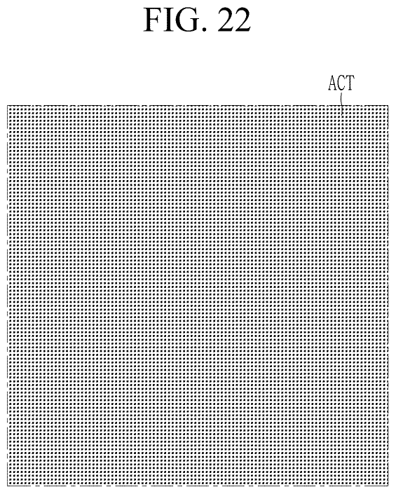

FIG. 22 to FIG. 25 illustrate in detail a configuration of doping fluorine by the same method as in FIG. 11 with respect to a semiconductor layer having a different structure. Referring to FIG. 22, a semiconductor layer ACT is first formed.

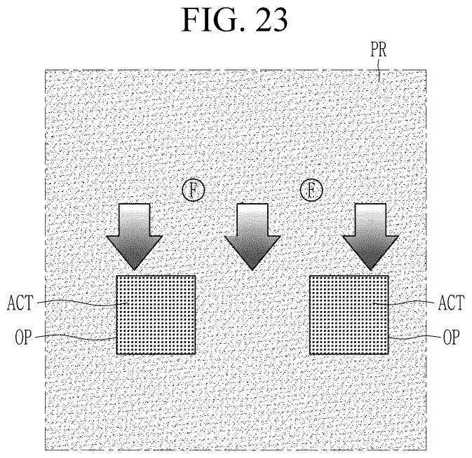

Next referring to FIG. 23, a photoresist PR is formed on the semiconductor layer. In this case, the photoresist PR has an opening OP overlapping a partial area of the semiconductor layer ACT. Accordingly, the partial area of the semiconductor layer ACT is exposed without overlapping the photoresist PR. Thereafter, fluorine is doped. In this case, the fluorine is doped only in the semiconductor layer that is not covered by the photoresist PR.

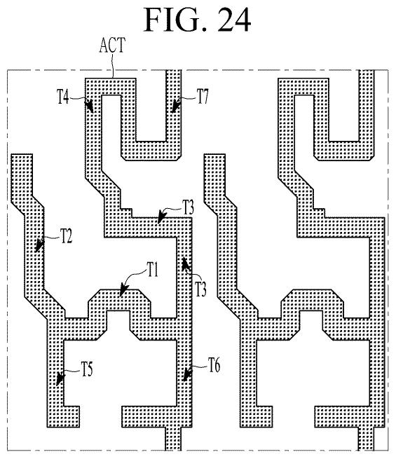

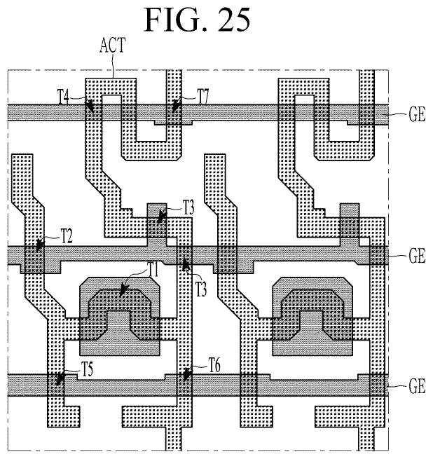

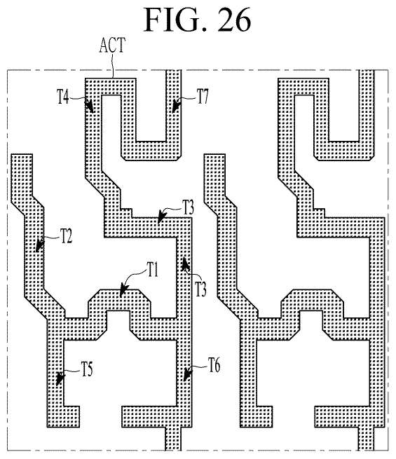

Next, referring to FIG. 24, the semiconductor layer is patterned. Next, referring to FIG. 25, a gate conductive layer GE is positioned, and a plurality of transistors T1-T7 are formed. In FIG. 25, the first transistor T1 is an area doped with fluorine in FIG. 23. Since the remaining transistors T2-T7 are covered by the photoresist PR during the fluorine doping process, fluorine doping is not performed. Accordingly, the fluorine concentration of the first transistor is higher than that of the other transistors. Specifically, the fluorine concentration of the first transistor T1 may be 2 to 10 times the fluorine concentration of the other transistors T2-T7.

FIG. 26 to FIG. 29 illustrate in detail a configuration of doping fluorine by the same method as in FIG. 10 with respect to a semiconductor layer having a different structure. Referring to FIG. 26, a semiconductor layer pattern ACT configuring a plurality of transistors is formed by patterning a semiconductor layer.

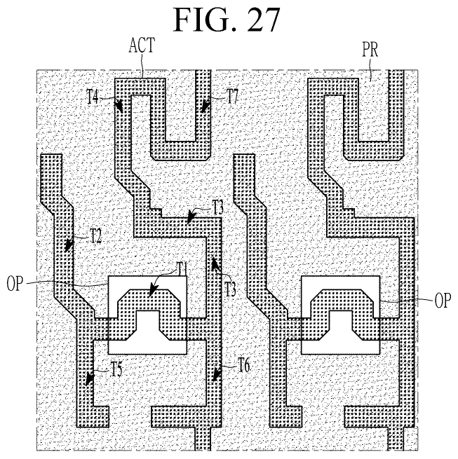

Next, referring to FIG. 27, a photoresist PR is formed. In this case, the photoresist PR has an opening OP overlapping the first transistor T1. Accordingly, the first transistor T1 is exposed without overlapping with the photoresist PR.

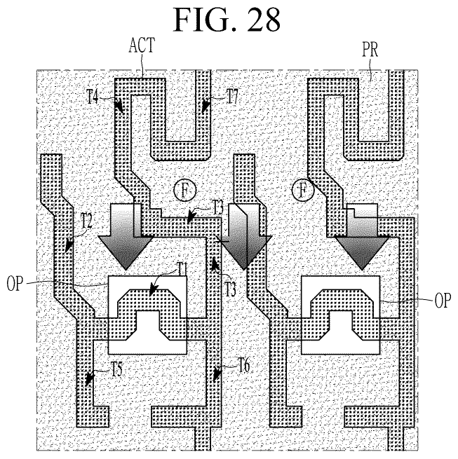

Next, referring to FIG. 28, fluorine is doped. In this case, the fluorine is doped only in the first transistor T1 that is not covered by the photoresist PR. In the case of other transistors (e.g., T2-T7), they are covered with the photoresist PR, so they are not doped with fluorine.

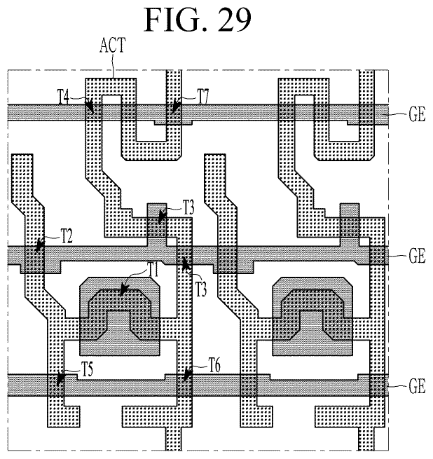

Next, referring to FIG. 29, a gate conductive layer GE is positioned, and a plurality of transistors T1-T7 are formed.

Since only the first transistor is doped with fluorine in the manufacturing method, the fluorine concentration of the first transistor T1 is higher than that of the other transistors. Specifically, the fluorine concentration of the first transistor may be 2 to 10 times the fluorine concentration of the other transistors.

Hereinafter, a structure of a display device according to an embodiment will be described in detail with reference to the accompanying drawings. However, this structure is only an example, and the disclosure is not limited thereto.

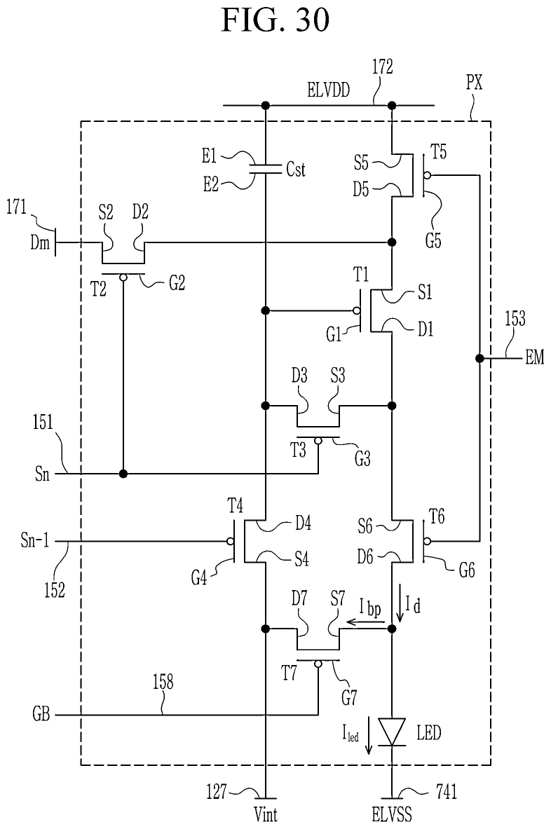

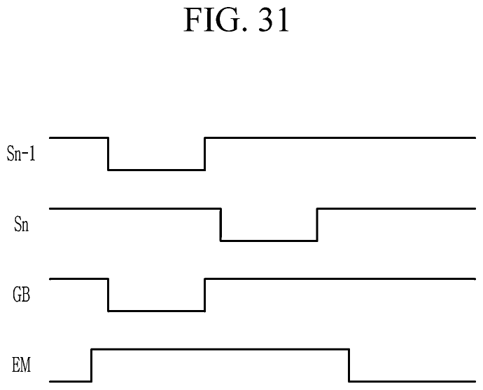

FIG. 30 illustrates an equivalent circuit diagram of one pixel in a light emitting display device according to an embodiment, and FIG. 31 illustrates a timing chart of a signal applied to one pixel of a light emitting display device according to an embodiment.

Referring to FIG. 30, a pixel PX of a light emitting diode display includes a plurality of transistors T1, T2, T3, T4, T5, T6, and T7, a storage capacitor Cst, and a light emitting diode LED, which are connected to several signal lines 127, 151, 152, 153, 158, 171, 172, and 741.

The light emitting diode display includes a display area in which an image is displayed, and the pixels PX are arranged in various shapes in the display area.

The plurality of transistors T1, T2, T3, T4, T5, T6, and T7 may include the driving transistor T1, a switching transistor connected to a scan line 151, that is, a second transistor T2 and the third transistor T3, and other transistors (hereinafter referred to as compensation transistors) that are transistors for performing operations necessary to operate the light emitting diode LED. These compensation transistors T4, T5, T6, and T7 may include a fourth transistor T4, a fifth transistor T5, a sixth transistor T6, and a seventh transistor T7.

The plurality of signal lines 127, 151, 152, 153, 158, 171, 172, and 741 may include the scan line 151, a previous scan line 152, an emission control line 153, a bypass control line 158, a data line 171, a driving voltage line 172, an initialization voltage line 127, and a common voltage line 741. The bypass control line 158 may be a portion of the previous scan line 152, or may be electrically connected thereto. Alternatively, the bypass control line 158 may be a portion of the scan line 151, or may be electrically connected thereto.

The scan line 151 is electrically connected to a gate driver to transmit a scan signal Sn to the second transistor T2 and the third transistor T3. The previous scan line 152 is electrically connected to the gate driver to transmit a previous scan signal Sn−1 applied to the pixel PX positioned at a previous stage to the fourth transistor T4. The emission control line 153 is electrically connected to an emission controller, and it transmits an emission control signal EM that controls an emission time of the light emitting diode LED to the fifth transistor T5 and the sixth transistor T6. The bypass control line 158 transmits a bypass signal GB to the seventh transistor T7.

The data line 171 is a wire that transmits a data voltage Dm generated by a data driver circuit (not shown), and luminance at which the light emitting diode LED (also referred to as a light emitting element) emits light is changed according to the data voltage Dm. The driving voltage line 172 applies a driving voltage ELVDD. The initialization voltage line 127 transmits an initialization voltage Vint that initializes the driving transistor T1. The common voltage line 741 applies a common voltage ELVSS. Voltages applied to the driving voltage line 172, the initialization voltage line 127, and the common voltage line 741 may be constant.

Hereinafter, some of the transistors in the display device will be described.

The driving transistor T1 is a transistor that adjusts an amount of a current outputted according to the data voltage Dm applied thereto. An outputted driving current Id may be applied to the light emitting diode LED to adjust brightness of the light emitting diode LED according to the data voltage Dm. To this end, a first electrode S1 of the driving transistor T1 may be disposed to receive the driving voltage ELVDD. The first electrode S1 is electrically connected to the driving voltage line 172 via the fifth transistor T5. In addition, the first electrode S1 of the driving transistor T1 is electrically connected to a second electrode D2 of the second transistor T2 to receive the data voltage Dm. A second electrode D1 (output electrode) of the driving transistor T1 is disposed to be able to output a current toward the light emitting diode LED. The second electrode D1 of the driving transistor T1 is electrically connected to an anode of the light emitting diode LED via the sixth transistor T6. Meanwhile, a gate electrode G1 is electrically connected to one electrode (a second storage electrode E2) of the storage capacitor Cst. Accordingly, a voltage of the gate electrode G1 may be changed according to a voltage stored in the storage capacitor Cst, and accordingly, the driving current Id outputted from the driving transistor T1 may be changed.

The second transistor T2 is a transistor that allows the data voltage Dm to be received into the pixel PX. A gate electrode G2 is electrically connected to the scan line 151, and a first electrode S2 is electrically connected to the data line 171. The second electrode D2 of the second transistor T2 is electrically connected to the first electrode S1 of the driving transistor T1. In a case that the second transistor T2 is turned on according to the scan signal Sn transmitted through the scan line 151, the data voltage Dm transmitted through the data line 171 may be transmitted to the first electrode S1 of the driving transistor T1.

The third transistor T3 is a transistor that allows a compensation voltage (Dm+Vth) that is changed as the data voltage Dm passes through the driving transistor T1 to be transmitted to the second storage electrode E2 of the storage capacitor Cst. A gate electrode G3 is electrically connected to the scan line 151, and a first electrode S3 is electrically connected to the second electrode D1 of the driving transistor T1. A second electrode D3 of the third transistor T3 is electrically connected to the second storage electrode E2 of the storage capacitor Cst and the gate electrode G1 of the driving transistor T1. The third transistor T3 may be turned on according to the scan signal Sn transmitted through the scan line 151 to connect the gate electrode G1 and the second electrode D1 of the driving transistor T1 and to connect the second electrode D1 of the driving transistor T1 and the second storage electrode E2 of the storage capacitor Cst.

The fourth transistor T4 can be constructed and arranged to initialize the gate electrode G1 of the driving transistor T1 and the second storage electrode E2 of the storage capacitor Cst. A gate electrode G4 is electrically connected to the previous scan line 152, and a first electrode S4 is electrically connected to the initialization voltage line 127. A second electrode D4 of the fourth transistor T4 is electrically connected to the second storage electrode E2 of the storage capacitor Cst and the gate electrode G1 of the driving transistor T1 via the second electrode D3 of the third transistor T3. The fourth transistor T4 can be constructed and arrange to transmit the initialization voltage Vint to the gate electrode of the driving transistor T1 and the second storage electrode E2 of the storage capacitor Cst according to the previous scan signal Sn−1 received through the previous scan line 152. Accordingly, a gate voltage of the gate electrode G1 of the driving transistor T1 and the storage capacitor Cst may be initialized. The initialization voltage Vint may have a low voltage value, and it may be a voltage capable of turning on the driving transistor T1.

The fifth transistor T5 is constructed and arranged to transmit the driving voltage ELVDD to the driving transistor T1. A gate electrode G5 is electrically connected to the light emission control line 153, and a first electrode S5 is electrically connected to the driving voltage line 172. A second electrode D5 of the fifth transistor T5 is electrically connected to the first electrode S1 of the driving transistor T1.

The sixth transistor T6 is constructed and arranged to transmit the driving current Id outputted from the driving transistor T1 to the light emitting diode LED. A gate electrode G6 is electrically connected to the light emission control line 153, and a first electrode S6 is electrically connected to the second electrode D1 of the driving transistor T1. A second electrode D6 of the sixth transistor T6 is electrically connected to the anode of the light emitting diode LED.

The fifth transistor T5 and the sixth transistor T6 may be simultaneously turned on according to the light emission control signal EM transmitted through the light emission control line 153, and in a case that the driving voltage ELVDD is applied to the first electrode S1 of the driving transistor T1 through the fifth transistor T5, the driving transistor T1 is constructed and arranged to output the driving current Id according to a voltage of the gate electrode G1 of the driving transistor T1 (that is, a voltage of the second storage electrode E2 of the storage capacitor Cst). The outputted driving current Id may be transmitted to the light emitting diode LED through the sixth transistor T6. The light emitting diode LED may emit light as a current I_{led} flows therethrough.

The seventh transistor T7 is constructed and arranged to initialize the anode of the light emitting diode LED. A gate electrode G7 is electrically connected to the bypass control line 158, a first electrode S7 is electrically connected to the anode of the light emitting diode LED, and a second electrode D7 is electrically connected to the initialization voltage line 127. The bypass control line 158 may be connected to the previous scan line 152, and the bypass signal GB is applied as the same timing signal as the previous scan signal Sn−1. The bypass control line 158 may not be connected to the previous scan line 152 to transmit a separate signal from the previous scan signal Sn−1. In a case that the seventh transistor T7 is turned on according to the bypass signal GB, the initialization voltage Vint may be applied to the anode of the light emitting diode LED such that the light emitting diode LED is initialized.

A first storage electrode E1 of the storage capacitor Cst is electrically connected to the driving voltage line 172, and the second storage electrode E2 thereof is electrically connected to the gate electrode G1 of the driving transistor T1, the second electrode D3 of the third transistor T3, and the second electrode D4 of the fourth transistor T4. As a result, the second storage electrode E2 is constructed and arranged to determine a voltage of the gate electrode G1 of the driving transistor T1, and the second storage electrode E2 may be constructed and arranged to receive the data voltage Dm through the second electrode D3 of the third transistor T3, or the initialization voltage Vint through the second electrode D4 of the fourth transistor T4.

Meanwhile, the anode of the light emitting diode LED is electrically connected to the second electrode D6 of the sixth transistor T6 and the first electrode S7 of the seventh transistor T7, and a cathode thereof is electrically connected to the common voltage line 741 that is constructed and arranged to transmit the common voltage ELVSS.

In the embodiment of FIG. 30, the pixel circuit includes seven transistors T1 to T7 and one capacitor Cst, but is not limited thereto, and the number of transistors, the number of capacitors, and their connection may be variously changed.

In the embodiment of FIG. 30, the first transistor T1 may be doped with fluorine, and the remaining transistors T2 through T7 may not be doped with fluorine. Accordingly, the fluorine concentration of the first transistor T1 may be higher than that of the remaining transistors T2, T3, T4, T5, T6, and T7. Specifically, the fluorine concentration of the first transistor T1 may be 2 to 10 times the fluorine concentration of the remaining transistors T2, T3, T4, T5, T6, and T7.

An operation of one pixel of the light emitting diode display according to the embodiment will be described with reference to FIG. 30 and FIG. 31.

During an initialization period, the previous scan signal Sn−1 of a low level may be supplied to the pixel PX through the second scan line 152. In this case, the fourth transistor T4 to which the previous scan signal Sn−1 of the low level is applied is turned on, so that the initializing voltage Vint may be applied to the gate electrode G1 of the driving transistor T1 and the second storage electrode E2 of the storage capacitor Cst through the fourth transistor T4. Accordingly, the driving transistor T1 and the storage capacitor Cst may be initialized. Since the initialization voltage Vint is a low voltage, the driving transistor T1 may be turned on.

Meanwhile, during an initialization period, the bypass signal GB of a low level may be applied to the seventh transistor T7. The seventh transistor T7 to which the bypass signal GB of the low level is applied may be turned on, so that the initializing voltage Vint may be applied to the anode of the light emitting diode LED through the seventh transistor T7. As a result, the anode of the light emitting diode LED may be initialized.

Thereafter, during a data writing period, the scan signal Sn of a low level may be supplied to the pixel PX through the scan line 151. The second transistor T2 and the third transistor T3 may be turned on by the scan signal Sn of the low level.

In a case that the second transistor T2 is turned on, the data voltage Dm may be input to the first electrode S1 of the driving transistor T1 through the second transistor T2.

In addition, during the data writing period, the third transistor T3 may be turned on, and as a result, the second electrode D1 of the driving transistor T1 may be electrically connected to the gate electrode G1 and the second storage electrode E2 of the storage capacitor Cst. The gate electrode G1 and the second electrode D1 of the driving transistor T1 are connected to be diode-connected. In addition, the driving transistor T1 may be turned on because a low voltage (the initialization voltage Vint) is applied to the gate electrode G1 during the initialization period. As a result, the data voltage Dm inputted to the first electrode S1 of the driving transistor T1 may pass through the channel of the driving transistor T1, and may be outputted from the second electrode D1 and then passed through the third transistor T3 to be stored in the second storage electrode E2 of the storage capacitor Cst.

In this case, the voltage applied to the second storage electrode E2 may be changed according to the threshold voltage Vth of the driving transistor T1, and in a case that the data voltage Dm is applied to the first electrode S1 of the driving transistor T1 and the initialization voltage Vint is applied to the gate electrode G1 of the driving transistor T1, the voltage outputted to the second electrode D1 thereof may have a value of Vgs+Vth. Here, Vgs is a difference between the voltages applied to the gate electrode G1 and the first electrode S1 of the driving transistor T1, so it may have a value of Dm−Vint. Therefore, the voltage that is outputted from the second electrode D1 and is stored in the second storage electrode E2 may have a value of Dm−Vint+Vth.

Thereafter, during a light emitting period, since the light emitting control signal EM supplied from the light emitting control line 153 is a low level, the fifth transistor T5 and the sixth transistor T6 are turned on. As a result, the driving voltage ELVDD is applied to the first electrode S1 of the driving transistor T1, and the second electrode D1 of the driving transistor T1 is electrically connected to the light emitting diode LED. In the driving transistor T1, the driving current Id may be generated according to a difference between the voltage of the gate electrode G1 and the voltage (that is, the driving voltage ELVDD) of the first electrode S1. The driving current Id of the driving transistor T1 may have a value proportional to a squared value of ‘Vgs−Vth’. Herein, the Vgs is a difference between voltages applied to both terminals of the storage capacitor Cst, and since the Vgs is ‘Vg−Vs’, it may be ‘Dm−Vint+Vth−ELVDD’. Herein, in a case that Vgh−Vth′ is obtained by subtracting Vth, it is ‘Dm−Vint−ELVDD’. That is, the driving current Id of the driving transistor T1 has a current independent of the threshold voltage Vth of the driving transistor T1 as an output.

Therefore, it is possible to output an output current of the driving transistor T1 to be constant even though the driving transistors T1 disposed in respective pixels PX have different threshold voltages Vth due to process dispersion, thereby improving non-uniformity of the characteristics thereof.

In the above calculation formulas, in a case that the transistor is a p-type transistor using a polycrystalline semiconductor, the Vth may be a value that is slightly larger than 0 or a negative value. In addition, signs of + and − may be changed depending on a direction in which the voltage is calculated. However, even in this case, the driving current Id which is an output current of the driving transistor T1 may have a value that is independent of the threshold voltage Vth.

In a case that the above-described light emitting period ends, the same operation may be repeated from the initialization period.

One of the first electrode and the second electrode of each of the plurality of transistors T1, T2, T3, T4, T5, T6, and T7 may be a source electrode and the other thereof may be a drain electrode, depending on a direction in which a voltage or current is applied.

Meanwhile, in some embodiments, in a case that the seventh transistor T7 initializes the anode of the light emitting diode LED in the initialization period, it may prevent even a small amount of current emitted under a condition in which the driving transistor T1 is not actually turned on from flowing toward the light emitting diode LED. In this case, a small amount of current may be discharged through the seventh transistor T7 to a terminal of the initializing voltage Vint stage as a bypass current Ibp. Accordingly, the light emitting diode LED does not emit unnecessary light, so that a black gray may be displayed more clearly and a contrast ratio may be improved. In this case, the bypass signal GB may be a signal having different timing from that of the previous scan signal Sn−1. In some exemplary embodiments, the seventh transistor T7 may be omitted.

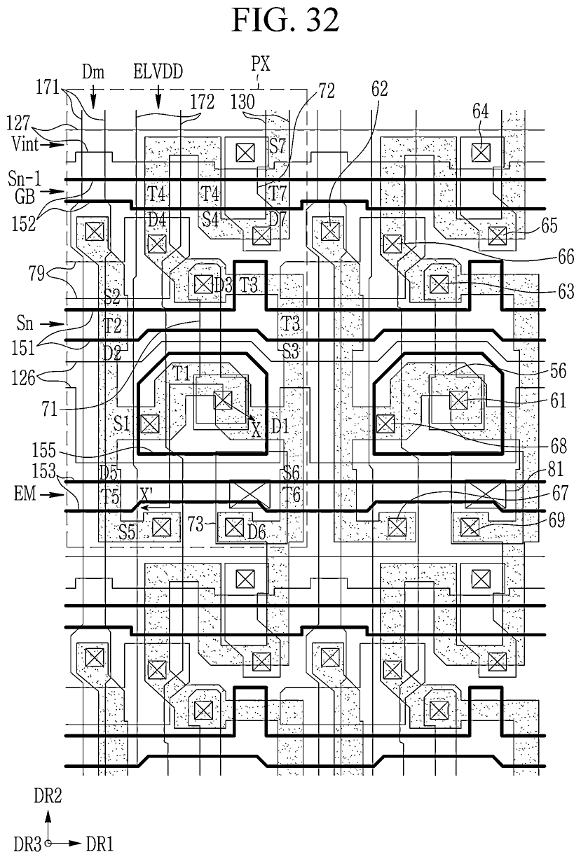

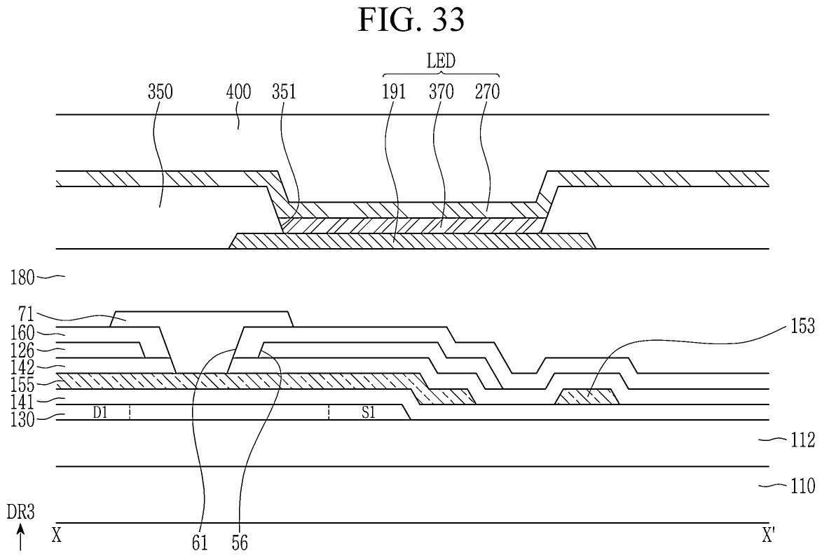

Hereinafter, a pixel of the light emitting diode display according to the embodiment will be described with reference to FIG. 32 and FIG. 33 together with FIG. 30 and FIG. 31. FIG. 32 illustrates a layout view of one pixel area of a light emitting display device according to an embodiment, and FIG. 33 illustrates a schematic cross-sectional view taken along line X-X′ in FIG. 32.

Referring to FIG. 32, the light emitting diode display according to the embodiment includes the scan line 151 that extends along a first direction DR1 and may transmit the scan signal Sn, the previous scan line 152 that may transmit the previous scan signal Sn−1, the emission control line 153 that may transmit the emission control signal EM, and the initialization voltage line 127 that may transmit the initialization voltage Vint. The bypass signal GB may be transmitted through the previous scan line 152.

The light emitting diode display includes the data line 171 that extends along a second direction DR2 orthogonal to the first direction DR1 and may transmit the data voltage Dm, and the driving voltage line 172 that may transmit the driving voltage ELVDD.

The light emitting diode display includes the driving transistor T1, the second transistor T2, the third transistor T3, the fourth transistor T4, the fifth transistor T5, the sixth transistor T6, the seventh transistor T7, the storage capacitor Cst, and the light emitting diode LED.

Each of the channels of the driving transistor T1, the second transistor T2, the third transistor T3, the fourth transistor T4, the fifth transistor T5, the sixth transistor T6, and the seventh transistor T7 is disposed within a semiconductor layer 130 that extends along the directions DR1 and DR2. In addition, at least portions of the first and second electrodes of the plurality of transistors T1, T2, T3, T4, T5, T6, and T7 also may be disposed in the semiconductor layer 130. The semiconductor layer 130 (a portion in which a shading is added in FIG. 32) may be variously bent. The semiconductor layer 130 may include a polycrystalline semiconductor or an oxide semiconductor such as polysilicon.

The semiconductor layer 130 includes a channel doped with an n-type impurity or a p-type impurity, and a first doped area and a second doped area that are positioned at respective sides of the channel and have a higher doping concentration than that of the impurities doped in the channel. The first doped area and the second doped area correspond to the first and second electrodes of a plurality of transistors T1, T2, T3, T4, T5, T6, and T7, respectively. In a case that one of the first doped area and the second doped area is a source area, the other one thereof is a drain area. In addition, an area between the first electrode and the second electrode of the different transistors in the semiconductor layer 130 may also be doped so that the two transistors may be electrically connected to each other.

Each of the channels of the plurality of transistors T1, T2, T3, T4, T5, T6, and T7 overlaps the gate electrode of each of the transistors T1, T2, T3, T4, T5, T6, and T7, and is positioned between the first electrode and the second electrode of each of the transistors T1, T2, T3, T4, T5, T6, and T7. The plurality of transistors T1, T2, T3, T4, T5, T6, and T7 may have a substantially same stacked structure. Hereinafter, the driving transistor T1 will be mainly described in detail, and the remaining transistors T2, T3, T4, T5, T6, and T7 will be briefly described.

The driving transistor T1 includes a channel, a first gate electrode 155, a first electrode S1, and a second electrode D1. The channel of the driving transistor T1 is disposed or positioned between the first electrode S1 and the second electrode D1, and overlaps the first gate electrode 155 in a plan view. The first gate electrode 155 overlaps the channel in a plan view. The first and second electrodes S1 and D1 are respectively disposed at both sides of the channel. An extended portion of a storage line 126 is isolated and disposed on the first gate electrode 155. The extended portion of the storage line 126 overlaps the gate electrode 155 with a second gate insulating film therebetween in a plan view to form the storage capacitor Cst. The extended portion of the storage line 126 is a first storage electrode (E1 of FIG. 30) of the storage capacitor Cst, and the first gate electrode 155 is a second storage electrode (E2 of FIG. 30). The extended portion of the storage line 126 may be provided with an opening 56 formed so that the first gate electrode 155 may be connected to a first data connecting member 71. In the opening 56, an upper surface of the first gate electrode 155 and the first data connecting member 71 may be electrically connected through a contact hole 61. The first data connecting member 71 is electrically connected to the second electrode D3 of the third transistor T3 to connect the gate electrode 155 of the driving transistor T1 and the second electrode D3 of the third transistor T3.

The gate electrode of the second transistor T2 may be a portion of the scan line 151. The data line 171 is electrically connected to the first electrode S2 of the second transistor T2 through a contact hole 62. The first electrode S2 and the second electrode D2 may be positioned on the semiconductor layer 130.

The third transistor T3 may be configured of two transistors adjacent to each other. In the pixel PX of FIG. 32, symbol T3 is illustrated at a left side and a lower side with respect to the bent portion of the semiconductor layer 130. These two portions each is constructed and arranged to operate as the third transistor T3, and the first electrode S3 of one third transistor T3 is electrically connected to the second electrode D3 of the other third transistor T3. The gate electrode of the two transistors T3 may be a portion of the scan line 151 or a portion protruding upward from the scan line 151. Such a structure may be regarded as a dual gate structure and may block a leakage current from flowing. The first electrode S3 of the third transistor T3 is electrically connected to the first electrode S6 of the sixth transistor T6 and the second electrode D1 of the driving transistor T1. The second electrode D3 of the third transistor T3 is electrically connected to the first data connecting member 71 through a contact hole 63.

The fourth transistor T4 is also configured as two fourth transistors T4, and the two fourth transistors T4 are formed at a portion in which the previous scan line 152 and the semiconductor layer 130 meet. The gate electrode of the fourth transistor T4 may be a portion of the previous scan line 152. The first electrode S4 of one fourth transistor T4 is electrically connected to the second electrode D4 of the other fourth transistor T4. Such a structure may be regarded as a dual gate structure and may be constructed and arranged to block a leakage current. A second data connecting member 72 is electrically connected to the first electrode S4 of the fourth transistor T4 through a contact hole 65, and the first data connecting member 71 is electrically connected to the second electrode D4 of the fourth transistor T4 through the contact hole 63.

As described above, by using the dual gate structure in the third transistor T3 and the fourth transistor T4, it is possible to effectively prevent a leakage current by blocking an electron movement path of the channel in an OFF state.

The gate electrode of the fifth transistor T5 may be a portion of the emission control line 153. The driving voltage line 172 is electrically connected to the first electrode S5 of the fifth transistor T5 through a contact hole 67, and the second electrode D5 thereof is electrically connected to the first electrode S1 of the driving transistor T1 through the semiconductor layer 130.

The gate electrode of the sixth transistor T6 may be a portion of the emission control line 153. A third data connecting member 73 is electrically connected to the second electrode D6 of the sixth transistor T6 through a contact hole 69, and the first electrode S6 is electrically connected to the second electrode D1 of the driving transistor through the semiconductor layer 130.

The gate electrode of the seventh transistor T7 may be a portion of the previous scan line 152. The first electrode S7 of the seventh transistor T7 is electrically connected to the second electrode D6 of the sixth transistor T6, and the second electrode D7 is electrically connected to the first electrode S4 of the fourth transistor T4.

The first transistor T1 may be doped with fluorine, and the remaining transistors may not be doped with fluorine. Accordingly, the fluorine concentration of the first transistor T1 may be higher than that of the remaining transistors T2, T3, T4, T5, T6, and T7. Specifically, the fluorine concentration of the first transistor T1 may be 2 to 10 times the fluorine concentration of the remaining transistors T2, T3, T4, T5, T6, and T7.

The storage capacitor Cst includes the first storage electrode E1 and the second storage electrode E2 which overlap each other with a second gate insulating film 142 therebetween. The second storage electrode E2 corresponds to the gate electrode 155 of the driving transistor T1, and the first storage electrode E1 may be the extended portion of the storage line 126. Herein, the second gate insulating film 142 becomes a dielectric, and a capacitance may be determined by a charge stored in the storage capacitor Cst and a voltage difference between the first and second storage electrodes E1 and E2. By using the first gate electrode 155 as the second storage electrode E2, a space capable of forming the storage capacitor Cst in a space that is narrowed by the channel of the driving transistor T1 occupying a large area in the pixel may be secured.

The driving voltage line 172 is electrically connected to the first storage electrode E1 through a contact hole 68. Therefore, the storage capacitor Cst stores a charge corresponding to a difference between the driving voltage ELVDD transmitted to the first storage electrode E1 through the driving voltage line 172 and the gate voltage Vg of the gate electrode 155.

The second data connecting member 72 is electrically connected to the initializing voltage line 127 through a contact hole 64. The first electrode is electrically connected to the third data connecting member 73 through a contact hole 81. The first electrode may be a pixel electrode.

A parasitic capacitor control pattern 79 may be positioned between the dual gate electrodes of the compensation transistor T3. A parasitic capacitor exists in the pixel, and image quality characteristics may change in a case that the voltage applied to the parasitic capacitor is changed. The driving voltage line 172 is electrically connected to the parasitic capacitor control pattern 79 through a contact hole 66. Therefore, it is possible to prevent the image quality characteristic from being changed by applying the driving voltage ELVDD, which is a constant DC voltage, to the parasitic capacitor. The parasitic capacitor control pattern 79 may be formed in a different area from that shown, and a voltage other than the driving voltage ELVDD may be applied.

One end of the first data connecting member 71 is electrically connected to the gate electrode 155 through the contact hole 61, and the other end thereof is electrically connected to the second electrode D3 of the third transistor T3 and the second electrode D4 of the fourth transistor T4 through the contact hole 63.

One end of the second data connecting member 72 is electrically connected to the first electrode S4 of the fourth transistor T4 through the contact hole 65, and the other end thereof is electrically connected to the initialization voltage line 127 through the contact hole 64.

The third data connecting member 73 is electrically connected to the second electrode of the sixth transistor T6 through the contact hole 69.

Hereinafter, a sectional structure of the light emitting diode display according to the embodiment will be described according to the stacked order with reference to FIG. 33 in addition to FIG. 32.

The light emitting diode display according to the embodiment includes the substrate 110.

The substrate 110 may include a plastic layer and a barrier layer. The plastic layer and the barrier layer may be alternatively stacked.

The plastic layer may include one of polyethersulphone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate (PC), poly(arylene ether sulfone), and a combination thereof.

The barrier layer may include at least one of a silicon oxide, a silicon nitride, and an aluminum oxide, but is not limited thereto, and may include any inorganic material. For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

A buffer layer 112 is positioned on the substrate 110. The buffer layer 112 may include an inorganic insulating material such as a silicon oxide, a silicon nitride, or an aluminum oxide, or may include an organic insulating material such as a polyimide acryl.

The semiconductor layer 130 that includes the channels of the plurality of transistors T1, T2, T3, T4, T5, T6, and T7, the first electrode, and the second electrode is disposed on the buffer layer 112.

A first gate insulating film 141 covering the semiconductor layer 130 is disposed thereon. A first gate conductor including a first gate electrode 155, a scan line 151, a previous scan line 152, and an emission control line 153 is positioned on the first gate insulating film 141.

A second gate insulating film 142 is positioned on the first gate conductor to cover the first gate conductor. The first gate insulating film 141 and the second gate insulating film 142 may include an inorganic insulating material such as a silicon nitride, a silicon oxide, and an aluminum oxide, or an organic insulating material.

A second gate conductor including a storage line 126, an initialization voltage line 127, and a parasitic capacitor control pattern 79 is positioned on the second gate insulating film 142.

An interlayer insulating film 160 is positioned on the second gate conductor to cover the second gate conductor. The interlayer insulating film 160 may include an inorganic insulating material such as a silicon nitride, a silicon oxide, and an aluminum oxide, or an organic insulating material.

A data conductor including a data line 171, a driving voltage line 172, a first data connecting member 71, a second data connecting member 72, and a third data connecting member 73 is positioned on the interlayer insulating film 160. The first data connecting member 71 may be connected to the first gate electrode 155 through the contact hole 61.

A passivation film 180 is positioned on the data conductor to cover it. The passivation film 180 may be a planarization film, and may include an organic insulating material or an inorganic insulating material.

A first electrode 191 is positioned on the passivation film 180. The first electrode 191 is electrically connected to the third data connecting member 73 through the contact hole 81 formed in the passivation layer 180.

A partition wall 350 is positioned on the passivation film 180 and the first electrode 191. The partition wall 350 has an opening 351 overlapping the first electrode 191. An emission layer 370 is positioned at the opening 351. A second electrode 270 is positioned on the emission layer 370 and the partition wall 350. The first electrode 191, the emission layer 370, and the second electrode 270 may form the light emitting diode LED. The first electrode 191 may be a pixel electrode, and the second electrode 270 may be a common electrode.

In some embodiments, the pixel electrode may be an anode which is a hole injection electrode, and the common electrode may be a cathode which is an electron injection electrode. In contrast, the pixel electrode may be a cathode, and the common electrode may be an anode. In a case that holes and electrons are injected into the light emitting layer from the pixel electrode and the common electrode, respectively, light is emitted in a case that excitons in which the injected holes and electrons are combined enter a ground state from an excited state.

An encapsulation layer 400 protecting the light emitting diode LED is positioned on the second electrode 270. The encapsulation layer 400 may be in contact with the second electrode 270 as shown, and in some embodiments, it may be spaced apart from the second electrode 270.

The encapsulation layer 400 may be a thin film encapsulation layer in which an inorganic film and an organic film are stacked, and may include a triple layer formed of an inorganic film, an organic film, and an inorganic film. In some embodiments, a capping layer and a functional layer may be positioned between the second electrode 270 and the encapsulation layer 400.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the following claims.

What is claimed is:

1. A display device comprising:
a first transistor comprising a first semiconductor layer and a second transistor comprising a second semiconductor layer, the first and second semiconductor layers positioned on a substrate; and
a light emitting diode connected to the first transistor, wherein
the first transistor is a driving transistor;
the second transistor is a switching transistor;
a first concentration of fluorine in the first semiconductor layer is higher than a second concentration of fluorine in the second semiconductor layer; and
a first difference between the first and second concentrations substantially at or near a first interface of the first and second semiconductor layers is larger than a second difference between the first and second concentrations at a second interface of the first and second semiconductor layers, the second interface further from the substrate than the first interface.

2. The display device of claim 1, wherein the first difference between the first and second concentrations is 2 to 10 times the second concentration.

3. The display device of claim 1, further comprising
a barrier layer that is positioned between the substrate and the first transistor and between the substrate and the second transistor,
wherein a third concentration of fluorine in an area of the barrier layer overlapping the first semiconductor layer is higher than a fourth concentration of fluorine in an area of the barrier layer overlapping the second semiconductor layer.

4. The display device of claim 3, wherein the third concentration is 2 to 10 times the fourth concentration.

5. The display device of claim 4, wherein the first difference between the first and second concentrations is larger than a third difference between the third concentration and the fourth concentration.

6. The display device of claim 1, wherein the first semiconductor layer and the second semiconductor layer are positioned on the same layer.

7. The display device of claim 1, wherein the fluorine concentration is measured by comparing Secondary-ion mass spectrometry (SIMS) Intensity.

8. The display device of claim 1, further comprising
a driving voltage line, a common voltage line, a data line, a scan line, a previous scan line, a bypass control line, an initialization voltage line, a third transistor, a fourth transistor, a fifth transistor, a sixth transistor, and a seventh transistor that are positioned on the substrate, wherein
the first transistor includes a first electrode electrically connected to a second electrode of the fifth transistor and a second electrode electrically connected to a first electrode of the third transistor, and constructed and arranged to control a driving current by application of a data voltage;
the second transistor includes a first electrode electrically connected to the data line and a second electrode electrically connected to a first electrode of the first transistor, and is constructed and arranged to turn on according to a scan signal of the scan line;
the third transistor includes a first electrode electrically connected to a second electrode of the first transistor and a second electrode electrically connected to a gate electrode of the first transistor, and is constructed and arranged to turn on according to the scan signal of the scan line;
the fourth transistor includes a first electrode electrically connected to the initialization voltage line and a second electrode electrically connected to a second electrode of the third transistor, and is constructed and arranged to turn on according to a previous scan signal received through the previous scan line;
the fifth transistor includes a first electrode electrically connected to the driving voltage line and a second electrode electrically connected to the first electrode of the first transistor, and is constructed and arranged to turn on by an emission signal of an emission control line;
the sixth transistor includes a first electrode electrically connected to the second electrode of the first transistor and a second electrode electrically connected to an anode of the light emitting diode, and is constructed and arranged to turn on by the emission signal of the emission control line;
the seventh transistor includes a first electrode electrically connected to the anode of the light emitting diode and a second electrode electrically connected to the initialization voltage line, and is constructed and arranged to turn on according to a bypass signal of the bypass control line; and
the first concentration of fluorine included in the first semiconductor layer of the first transistor is higher than concentrations of fluorine included in a third semiconductor layer of the third transistor, a fourth semiconductor layer of the fourth transistor, a fifth semiconductor layer of the fifth transistor, a sixth semiconductor layer of the sixth transistor, and a seventh semiconductor layer of the seventh transistor.

9. A manufacturing method of a display device, comprising:
forming a semiconductor layer on a substrate;
positioning a photoresist on the semiconductor layer;
forming an opening in the photoresist that exposes a portion of the semiconductor layer;
doping an area of the exposed semiconductor layer with fluorine; and
etching the semiconductor layer to form a first semiconductor layer and a second semiconductor layer,
wherein the first semiconductor layer is formed in the fluorine-doped area.

10. The manufacturing method of the display device of claim 9, wherein a fluorine concentration of the first semiconductor layer is higher than a fluorine concentration of the second semiconductor layer.

11. The manufacturing method of the display device of claim 9, wherein a fluorine concentration of the first semiconductor layer is 2 to 10 times a fluorine concentration of the second semiconductor layer.

12. The manufacturing method of the display device of claim 9, further comprising
forming a barrier layer between the substrate and the semiconductor layer,
wherein a fluorine concentration in an area of the barrier layer overlapping the first semiconductor layer is higher than a fluorine concentration in an area of the barrier layer overlapping the second semiconductor layer.

13. The manufacturing method of the display device of claim 12, wherein a fluorine concentration in an area of the barrier layer overlapping the first semiconductor layer is 2 to 10 times a fluorine concentration in an area of the barrier layer overlapping the second semiconductor layer.

14. The manufacturing method of the display device of claim 9, further comprising
crystallizing the first semiconductor layer and the second semiconductor layer.

15. A manufacturing method of a display device, comprising:
forming a semiconductor layer on a substrate;
patterning the semiconductor layer to form a first semiconductor layer and a second semiconductor layer;
positioning a photoresist on the first semiconductor layer and the second semiconductor layer;
forming an opening in the photoresist that exposes the first semiconductor layer; and
doping the first semiconductor layer with fluorine.

16. The manufacturing method of the display device of claim 15, wherein a fluorine concentration of the first semiconductor layer is higher than a fluorine concentration of the second semiconductor layer.

17. The manufacturing method of the display device of claim 15, wherein a fluorine concentration of the first semiconductor layer is 2 to 10 times a fluorine concentration of the second semiconductor layer.

18. The manufacturing method of the display device of claim 15, further comprising:
forming a barrier layer between the substrate and the semiconductor layer,
wherein a fluorine concentration in an area of the barrier layer overlapping the first semiconductor layer is higher than a fluorine concentration in an area of the barrier layer overlapping the second semiconductor layer.

19. The manufacturing method of the display device of claim 18, wherein a fluorine concentration in an area of the barrier layer overlapping the first semiconductor layer is 2 to 10 times a fluorine concentration in an area of the barrier layer overlapping the second semiconductor layer.

20. The manufacturing method of the display device of claim 15, further comprising:
crystallizing the first semiconductor layer and the second semiconductor layer.
